(19) United States
(12) Patent Application Publication
(10) Pub. No.: US 2026/0103821 A1
(43) Pub. Date: Apr. 16, 2026

(54) QUARTZ GLASS CRUCIBLE AND METHOD FOR PRODUCING SILICON SINGLE CRYSTAL USING SAME

(71) Applicant: SUMCO Corporation, Tokyo (JP)

(72) Inventors: Ken KITAHARA, Akita (JP); Hiroshi KISHI, Akita (JP); Eriko KITAHARA, Akita (JP); Kouta HASEBE, Akita (JP); Hideki FUJIWARA, Tokyo (JP)

(73) Assignee: SUMCO Corporation, Tokyo (JP)

(21) Appl. No.: 19/142,679

(22) PCT Filed: Oct. 24, 2023
(86) PCT No.: PCT/JP2023/038281

§ 371 Date: Jun. 24, 2025

(30) Foreign Application Priority Data
Jan. 13, 2023 (JP) 2023-003944

(51) Int. Cl. C30B 15/10; C03B 32/02; C30B 29/06

(52) U.S. Cl. CPC C30B 15/10; C03B 32/02; C30B 29/06

(57) ABSTRACT

A quartz glass crucible that allows an increase in strength during crystal pulling up, by forming a thick crystal layer on an outer surface of the crucible at an appropriate crystallization rate is provided. A quartz glass crucible includes a crucible base body made of silica glass and a crystallization accelerator-containing coating film formed on the outer surface of the crucible base body. 10 hours after a start of a heat treatment performed in an Ar atmosphere at a furnace temperature of 1580° C. and a furnace pressure of 20 Torr, a thickness of an outer surface crystal layer formed on the outer surface of the crucible base body is 0.21 to 0.5 mm and a crystallization rate is 21 to 50 μm/hr. A crystallization rate of the outer surface after 20 hours from the start of the heat treatment is 10 μm/hr or less.

### TECHNICAL FIELD

The present invention relates to a quartz glass crucible used for pulling up a silicon single crystal by a Czochralski method (CZ method). In addition, the present invention relates to a method for producing a silicon single crystal using such a quartz glass crucible.

### BACKGROUND ART

Most of silicon single crystals that serve as substrate materials of a semiconductor device are produced by a CZ method. In the CZ method, a polycrystalline silicon raw material is melted in a quartz glass crucible to generate a silicon melt, a seed crystal is immersed in the silicon melt, and the seed crystal is gradually pulled up while rotating the quartz glass crucible and the seed crystal, thereby growing a large single crystal at the lower end of the seed crystal. According to the CZ method, the yield of the large-diameter silicon single crystals can be increased.

A quartz glass crucible (silica glass crucible) is a container made of silica glass that holds a silicon melt during a silicon single crystal pulling up step. The inner side portion (inner layer) of the quartz glass crucible is formed of a transparent glass layer, which comes into contact with the silicon melt and thus contains substantially no bubbles, and the outer side portion (outer layer) is formed of a bubble-containing layer containing a number of bubbles to disperse the radiant heat from the outside to uniformly heat the inside of the crucible.

Regarding a quartz glass crucible that can appropriately crystallize quartz glass to suppress deformation of the crucible and the occurrence of cracks, for example, Patent Literature 1 describes an opaque quartz glass crucible having a low devitrification tendency, an Al concentration of 55 to 100 ppm by weight, a Ca concentration of 1.2 to 9.5 ppm by weight, and a molar concentration ratio (Al/Ca) of 15 or more.

In addition, Patent Literature 2 describes a quartz glass crucible including a high aluminum-containing layer that is made of quartz glass having a relatively high aluminum average concentration and is provided to constitute an outer surface of the quartz glass crucible, and a low aluminum-containing layer that is made of quartz glass having an aluminum average concentration lower than that of the high aluminum-containing layer and is provided inside the high aluminum-containing layer, in which the low aluminum-containing layer includes an opaque layer made of quartz glass containing a large number of minute bubbles, the high aluminum-containing layer is made of transparent or translucent quartz glass having a reduced bubble content as compared with the opaque layer, and the aluminum average concentration in the high aluminum-containing layer is 20 ppm or more. In this quartz glass crucible, even in a case where the high aluminum-containing layer is crystallized and the crystallization progresses toward the inside of the crucible, the aggregation or expansion of air bubbles does not occur, and thus the deformation of the crucible can be prevented.

Patent Literature 3 describes a quartz glass crucible including a crucible base body made of silica glass and a crystallization accelerator-containing layer provided on an outer surface of the crucible base body. A concentration of the crystallization accelerator contained in the crystallization accelerator-containing layer is 1.0×10¹³ atoms/cm² or more and 4.8×10¹⁵ atoms/cm² or less. The crystallization of the outer surface of the crucible is neither too fast nor too slow, and the crystallization has an appropriate time for strength development. Therefore, the crucible can withstand a single crystal pulling up step during long duration, and a gap between the crucible and the carbon susceptor is minimized, and the oxygen concentration and the crystal diameter of the silicon single crystal are stably controlled. The thickness of a crystal layer formed on the outer surface in a case where the heating is performed at a temperature of 1550° C. or higher and 1600° C. or lower for 25 hours is 200 to 500 μm.

The viscosity of the quartz glass crucible depends on a thermal history such as an arc melting temperature and a cooling rate, and the fictive temperature of the glass also changes in a case where the thermal history changes. The fictive temperature is correlated with the glass structure. The glass structure such as the content ratio of polycyclic rings in the glass can be estimated by a Raman spectroscopic analysis method. In the Raman spectroscopic analysis method, a content ratio of polycyclic rings in glass can be measured, and a fictive temperature can be specified from the result (see Non Patent Literature 1). A method of estimating a fictive temperature of glass by a Fourier transform infrared spectroscopy (FT-IR) method is also known (see Non Patent Literature 2).

### BACKGROUND ART LITERATURE

### Patent Literature

Patent Literature 1: Japanese Patent Laid-open Publication No. 2020-105062
Patent Literature 2: Japanese Republication of International Application No. 2018/051714
Patent Literature 3: International Publication No. WO2021/140729 Brochure

### Non Patent Literature

Non Patent Literature 1: Journal of A. E. Geissberger and F. L. Galeener, “Raman studies of vitreous SiO2 versus fictive temperature”, Phys. Rev. B, Vol. 28, pp. 3266-3271 (1983).
Non Patent Literature 2: A. Agarwal, K. M. Davis, and M. Tomozawa, “A simple IR spectroscopic method for determining fictive temperature of silica glasses”, J. Non-Cryst. Solids, Vol. 185, pp. 191-198 (1995).

### SUMMARY OF INVENTION

### Problems to be Solved by the Invention

As described above, in a case where the crystallization accelerator is applied onto the outer surface of the crucible, it is possible to improve the strength of the crucible by crystallizing the outer surface of the crucible. In particular, by increasing the coating concentration of the crystallization accelerator, crystallization is accelerated, and a thicker crystal layer can be formed.

However, in a case where the coating concentration of the crystallization accelerator is increased, the crystallization rate of the outer surface of the crucible is also increased, and in a case where the crystallization rate is too high, foaming-related peeling occur in the outer surface crystal layer of the crucible, which causes an issue of a decrease in strength due to deformation of the crucible. In a case where the crystallization rate of the outer surface of the crucible is too slow, the thickness of the outer surface crystal layer of the crucible is reduced, a desired strength cannot be secured, and issues such as buckling or inward deformation of the crucible may occur.

Therefore, an object of the present invention is to provide a quartz glass crucible capable of increasing the strength during a crystal pulling up step by forming a thick crystal layer on an outer surface of the crucible at an appropriate crystallization rate, and a method for producing a silicon single crystal using the quartz glass crucible.

### Means for Solving the Problems

To solve the above-described object, a quartz glass crucible according to the present invention includes a crucible base body made of silica glass and a crystallization accelerator-containing coating film formed on an outer surface of the crucible base body, in which, 10 hours after a start of a heat treatment performed in an Ar atmosphere at a furnace temperature of 1580° C. and a furnace pressure of 20 Torr, a thickness of an outer surface crystal layer formed on the outer surface of the crucible base body is 0.21 to 0.5 mm and a crystallization rate is 21 to 50 μm/hr, and a crystallization rate of the outer surface after 20 hours from the start of the heat treatment is 10 μm/hr or less.

According to the present invention, it is possible to form an outer surface crystal layer having a sufficient thickness of 200 μm or more on the outer surface of the crucible at a high temperature during the pulling up step of the silicon single crystal, and since the crystallization of the outer surface proceeds at an appropriate speed, neither too fast nor too slow, it is possible to form an outer surface crystal layer having a sufficient thickness while preventing foaming-related peeling of the outer surface crystal layer, and thereby impart a desired strength to the crucible.

In the present invention, it is preferable that a fictive temperature of the outer surface of the crucible base body is lower than a fictive temperature of an inside of the base body at a depth of 5 mm from the outer surface by 50° C. or more. In a case where the fictive temperature of the outer surface of the crucible base body is the same as or slightly lower than the inside of the base body, diffusion of the crystallization accelerator or substitution of the Si—O bond is less likely to occur, and a crystal layer having a sufficient thickness to the extent that a desired crucible strength can be exhibited in the initial stage of heating cannot be obtained. However, in a case where the fictive temperature of the outer surface of the crucible base body is lower than the inside of the base body by 50° C. or more, the Si—O bond is more likely to be broken on the outer surface than inside the crucible, and diffusion of the crystallization accelerator or substitution of the Si—O bond is likely to occur, which is effective in promoting crystallization.

In the present invention, it is preferable that an Al concentration in a first depth region within 10 mm from the outer surface of the crucible base body is higher than an Fe concentration in the first depth region. In addition, it is preferable that an Al concentration in a first depth region within 10 mm from the outer surface of the crucible base body is higher than a Ca concentration in the first depth region. Since the concentration of Al within 10 mm from the outer surface of the quartz glass crucible is higher than the concentration of Ca or Fe, crystallization in the thickness direction can be relatively promoted as compared with the in-plane direction of the crucible, and the outer surface of the crucible can be crystallized at an appropriate crystallization rate to a thickness at which the strength development effect is obtained.

It is preferable that the crystallization accelerator is Ba, and a Ba concentration in an outer surface crystal layer formed on the outer surface of the crucible base body after the heat treatment is less than 10 ppm. In a case where the Ba concentration in the outer surface crystal layer is 10 ppm or more, the concentration of the crystallization accelerator to be coated on the outer surface of the crucible base body is high, and crystallization during silicon single crystal pulling up is excessive, whereby foaming-related peeling of the outer surface crystal layer may occur. However, in a case where the Ba concentration in the outer surface crystal layer is less than 10 ppm, it is possible to promote the crystallization of the outer surface while suppressing foaming-related peeling of the outer surface crystal layer.

It is preferable that the crystallization accelerator-containing coating film contains barium carbonate and a thickener, and a Ba concentration in the crystallization accelerator-containing coating film is 1.0×10¹⁵ to 1.0×10¹⁸ atoms/cm². In a case where the Ba concentration is too low, unevenness occurs in the thickness and range of the crystal layer, and a crystal layer in which sufficient improvement in strength is expected is not formed. In addition, in a case where the Ba concentration is too high, there is a risk that the crystal layer may be broken during silicon single crystal pulling up because of excessive progress of crystallization. However, in a case where the Ba concentration is in a range of 1.0×10¹⁵ to 1.0×10¹⁸ atoms/cm², such an issue can be avoided, and crystallization of the outer surface can be promoted while suppressing foaming-related peeling of the outer surface crystal layer.

It is preferable that in a second depth region within two-thirds of a wall thickness of the crucible base body from the outer surface of the crucible base body, a B concentration is 0.02 to 0.05 ppm, an Mg concentration is 0.02 to 0.4 ppm, and a Cr concentration is 0.02 to 0.08 ppm. In a case where B, Mg, or Cr is present in the glass, a microstructure around the atom is a regularly arranged crystal structure. In a case where the impurities are present from the outer surface of the crucible base body to a certain depth, the crystallization rate in the depth direction from the outer surface toward the inner surface is increased. Therefore, the outer surface crystal layer can be made to be thick to a certain extent, and it is possible to attempt an improvement in the strength of the crucible.

It is preferable that the concentrations of B, Mg, and Cr in the second depth region within two-thirds of the wall thickness of the crucible base body from the outer surface of the crucible base body is higher than a concentration of B, Mg, and Cr in a third depth region within 2 mm from an inner surface of the crucible base body. By reducing the crystallization rate of the outer surface of the crucible base body, it is possible to prevent foaming-related peeling of the outer surface crystal layer, but the crucible is closely adapted to the carbon susceptor, whereby the softened silica glass penetrates into the gaps between the parts constituting the carbon susceptor, the effect of wrinkles that have occurred on the outer surface of the crucible extends even to the inner surface side of the crucible, and unevenness occurs on the inner surface of the crucible. However, by reducing the concentrations of B, Mg, and Cr on the inner surface side of the crucible base body, it is possible to prevent a decrease in viscosity of the silica glass and to suppress deformation of the inner surface side of the crucible.

In addition, in the method for producing of a silicon single crystal according to the present invention, a silicon single crystal is pulled up by the CZ method using the quartz glass crucible according to the present invention having the above-described features. According to the present invention, the manufacturing yield of a silicon single crystal can be increased.

Furthermore, the method for producing a quartz glass crucible according to the present invention includes a step of producing a crucible base body made of silica glass, and a step of forming a crystallization accelerator-containing coating film on an outer surface of the crucible base body, in which the step of producing the crucible base body includes a step of sequentially charging natural quartz powder and synthetic quartz powder into an inner surface of a rotating mold to form a deposited layer of raw material powder, a step of arc-melting the deposited layer of the raw material powder from an inside of the mold, and a step of finishing the arc melting and cooling the molten silica glass, and in the step of cooling the molten silica glass, the mold is heated to maintain a high temperature state. As a result, a fictive temperature difference between the outer surface of the crucible base body and the inside of the base body at a depth of 5 mm from the outer surface can be set to 50° C. or more. Therefore, it is possible to form an outer surface crystal layer having a sufficient thickness while preventing foaming-related peeling of the outer surface crystal layer, and to impart a desired strength to the crucible.

### Effects of the Invention

According to the present invention, it is possible to provide a quartz glass crucible capable of increasing the strength during crystal pulling up by forming a thick crystal layer on an outer surface of the crucible at an appropriate crystallization rate, and a method for producing the quartz glass crucible.

### BRIEF DESCRIPTION OF THE DRAWINGS

FIG. 1 is a schematic perspective view illustrating a configuration of a quartz glass crucible according to an embodiment of the present invention.

FIG. 2 is a schematic side sectional view of the quartz glass crucible illustrated in FIG. 1.

FIG. 3 is a schematic view for describing an impurity concentration distribution in a depth direction from an outer surface of a crucible base body.

FIG. 4 is a schematic diagram illustrating a method for producing a quartz glass crucible according to a rotational molding method.

FIG. 5 is a diagram for explaining a single crystal pulling up step using the quartz glass crucible according to the present embodiment, and is a schematic sectional view illustrating a configuration of a single crystal pulling apparatus.

FIG. 6 is a schematic side sectional view illustrating a crystallization state of the quartz glass crucible by heating.

### MODE FOR CARRYING OUT THE INVENTION

Hereinafter, preferred embodiments of the present invention are described in detail with reference to the accompanying drawings.

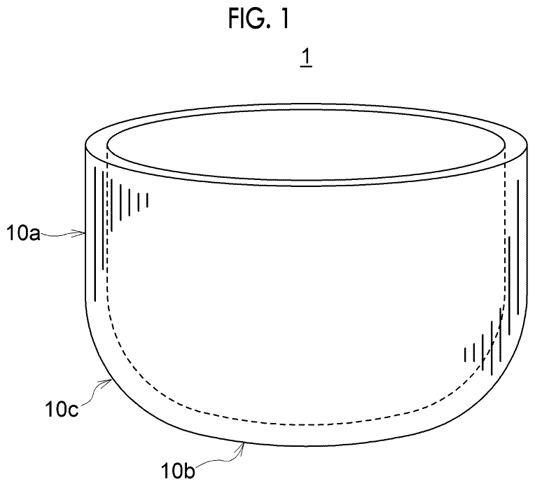

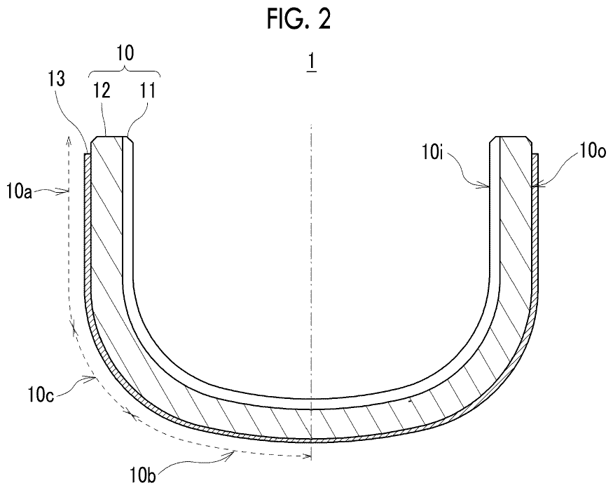

FIG. 1 is a schematic perspective view illustrating the configuration of a quartz glass crucible according to an embodiment of the present invention. In addition, FIG. 2 is a schematic side sectional view of the quartz glass crucible illustrated in FIG. 1.

As shown in FIG. 1 and FIG. 2, a quartz glass crucible 1 is a silica glass container for holding a silicon melt and has a cylindrical sidewall 10a, a bottom 10b provided below the sidewall 10a, and a corner 10c provided between the sidewall 10a and the bottom 10b. The bottom 10b is preferably a so-called round bottom that is gently curved, but may also be a so-called flat bottom. The corner 10c is a portion having a larger curvature than the bottom 10b. The boundary position between the sidewall 10a and the corner 10c and the boundary position between the bottom 10b and the corner 10c are positions where the curvature begins to change from a small curvature to a large curvature.

The aperture (diameter) of the quartz glass crucible 1 also varies depending on the diameter of the silicon single crystal ingot that is pulled up from the silicon melt, but is 18 inches (approximately 450 mm) or more, preferably 22 inches (approximately 560 mm) or more, and particularly preferably 32 inches (approximately 800 mm) or more. This is because such a large crucible is used for pulling up a large silicon single crystal ingot having a diameter of 300 mm or more, and is required not to affect the quality of the single crystal even with the long duration use.

The wall thickness of the crucible varies slightly depending on the part of the crucible, but is preferably 6 to 20 mm. In particular, it is preferable that the wall thickness of the sidewall 10a of the crucible of 18 inches or more is 6 mm or more, and the wall thickness of the sidewall 10a of the crucible of 22 inches or more is 7 mm or more, and the wall thickness of the sidewall 10a of the crucible of 32 inches or more is 10 mm or more. As a result, a large amount of silicon melt can be stably held at high temperature. It is preferable that the wall thickness of the corner 10c of the crucible is the largest and the wall thickness of the sidewall 10a and the bottom 10b of the crucible is smaller than that of the corner 10c of the crucible.

As shown in FIG. 2, a quartz glass crucible 1 includes a crucible base body 10 made of silica glass and a crystallization accelerator-containing coating film 13 formed on the outer surface 10o of the crucible base body 10. The crucible base body 10 mainly has a two-layer structure, and has a transparent layer 11 containing no bubbles (non-bubble layer) and a bubble layer 12 containing a large number of minute bubbles (opaque layer), and the crystallization accelerator-containing coating film 13 is provided outside the bubble layer 12.

The transparent layer 11 is a glass layer that configures the inner surface 10i of the crucible base body 10, which comes into contact with the silicon melt, and is provided to prevent a yield of the silicon single crystals from decreasing due to bubbles in the silica glass. Since the inner surface 10i of the crucible base body 10 reacts with the silicon melt to melt away, the bubbles in the vicinity of the inner surface cannot be trapped in the silica glass and the bubbles burst due to thermal expansion, and thus the crucible fragments (silica fragments) may be peeled. In a case where the crucible fragments released into the silicon melt are transported by melt convection to a growth interface of the silicon single crystal and are incorporated into the silicon single crystal, they cause dislocation in the silicon single crystal. In addition, in a case where the bubbles released into the silicon melt float up and reach a solid-liquid interface and are incorporated into the single crystal, they cause pinhole formation in the silicon single crystal.

Containing no bubbles in the transparent layer 11 means having a bubble content and a bubble size to the extent that the single crystallization rate does not decrease due to bubbles. Such a bubble content is, for example, 0.1 vol % or less, and the bubble diameter is, for example, 100 m or less.

The thickness of the transparent layer 11 is preferably 0.5 to 10 mm, and is set to an appropriate thickness for each portion of the crucible such that the bubble layer 12 is not exposed by completely vanishing the transparent layer 11 due to melting away during a crystal pulling up step. The transparent layer 11 is preferably provided over the entire crucible from the sidewall 10a to the bottom 10b of the crucible, but the transparent layer 11 can be omitted at the upper end portion of the crucible that does not come into contact with the silicon melt.

The air bubble content and the diameter of the air bubbles in the transparent layer 11 can be measured nondestructively using an optical detecting unit. The optical detecting unit includes a light-receiving device which receives transmitted light or reflected light of the light irradiating the crucible. As the light-receiving device, a digital camera including an optical lens and an imaging element can be used. As the irradiation light, X-rays, laser light, and the like as well as visible light, ultraviolet light, and infrared light can be used. Measurement results obtained by the optical detecting unit are received by an image processing device to calculate the diameter of bubbles and the bubble content per unit volume.

The bubble layer 12 is a principal glass layer of the crucible base body 10 located on the outer side than the transparent layer 11 and is provided to improve the heat retention property of the silicon melt in the crucible, and to heat the silicon melt in the crucible as uniformly as possible by dispersing radiant heat from a heater in a single crystal pulling apparatus. Therefore, the bubble layer 12 is provided over the entire crucible from the sidewall 10a to the bottom 10b. The thickness of the bubble layer 12 is substantially equal to a value obtained by subtracting the thickness of the transparent layer 11 from the thickness of the crucible base body 10, and varies depending on the part of the crucible.

The bubble content of the bubble layer 12 is higher than the transparent layer 11 and is preferably more than 0.1 vol % and 5 vol % or less. This is because in a case where the bubble content of the bubble layer 12 is 0.1 vol % or less, the bubble layer 12 cannot exhibit the required heat retention function. In addition, this is because when the bubble content of the bubble layer 12 exceeds 5 vol %, the crucible may be deformed due to the thermal expansion of the bubbles and decrease the yield of the single crystals, and further heat transfer property is insufficient. From the viewpoint of a balance between the heat retention property and the heat transfer property, the bubble content of the bubble layer 12 is particularly preferably 1% to 4% by volume. It should be noted that the above-described bubble content is a value obtained by measuring an unused crucible in a room temperature environment. The bubble content of the bubble layer 12 can be obtained, for example, by measuring the specific gravity (Archimedes method) of an opaque silica glass piece cut out from the crucible.

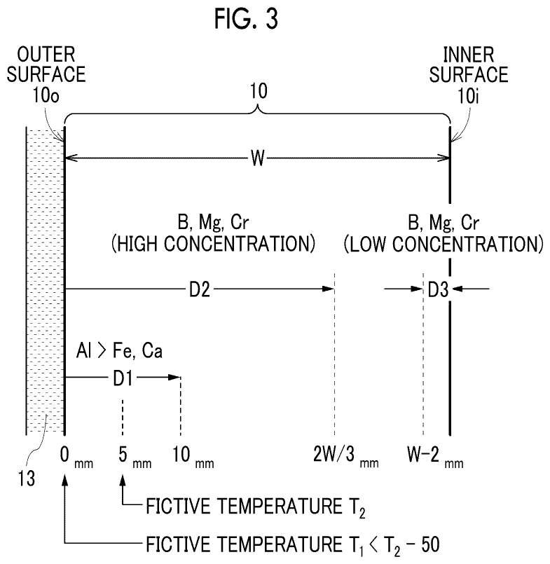

FIG. 3 is a schematic view for describing an impurity concentration distribution in a depth direction from an outer surface 10o of a crucible base body 10.

As shown in FIG. 3, it is preferable that the Al concentration in the first depth region D1 within at least 10 mm from the outer surface 10o of the crucible base body 10 is higher than the concentrations of Fe and Ca in the first depth region D1. In a case where the Al concentration of the outer surface layer portion within 10 mm from the outer surface 10o of the crucible base body 10 is lower than the Ca concentration or the Fe concentration, the crystallization accelerator applied to the outer surface 10o of the crucible base body 10 is less likely to be trapped in Al, and thus the crystallization in the in-plane direction is promoted as compared with the crystallization in the depth direction. To promote crystallization in the depth direction to the thickness at which the effect of developing the strength of the crucible is obtained, it is desirable to increase the Al concentration in the bulk to the extent at which the Al acts as an impurity that is a starting point of crystallization.

It is preferable that in a second depth region D2 within two-thirds of a wall thickness of the crucible base body 10 from the outer surface 10o of the crucible base body 10, a B concentration is 0.02 to 0.05 ppm, an Mg concentration is 0.02 to 0.4 ppm, and a Cr concentration is 0.02 to 0.08 ppm. In a case where B, Mg, or Cr is present in the glass, a microstructure around the atom is a regularly arranged crystal structure. In a case where the above-described impurities are present from the outer surface 10o of the crucible base body 10 to a sufficient depth region, crystallization in the depth direction from the outer surface 10o is accelerated, whereby a crystal layer of a certain thickness can be formed on the outer surface 10o of the crucible base body 10, and the strength of the crucible can be improved.

It is preferable that the concentrations of B, Mg, and Cr in the second depth region D2 within two-thirds of the wall thickness W of the crucible base body 10 from the outer surface 10o of the crucible base body 10 are higher than the concentrations of B, Mg, and Cr in a third depth region D3 within 2 mm from an inner surface 10i of the crucible base body 10. The thickness of the crucible base body 10 referred to here means the wall thickness at the measurement position of B, Mg, and Cr. A carbon susceptor that supports a quartz glass crucible during the crystal pulling up step is configured by combining a plurality of parts, and seams (grooves) between the parts are present on an inner surface of the divided carbon susceptor. Therefore, the outer surface 10o of the crucible base body 10 may soften before crystallization at a high temperature and may penetrate into a gap in the seam of carbon susceptor. In a case where such a penetration occurs, the outer surface 10o of the crucible base body 10 is deformed along the seam, and at the same time, the deformation of the inner surface 10i side of the crucible base body 10 is also induced. However, by reducing the concentrations of B, Mg, and Cr on the inner surface 10i side of the crucible base body 10, it is possible to prevent a decrease in viscosity of the silica glass and to suppress deformation of the inner surface side of the crucible.

It is preferable that a fictive temperature T₁ (° C.) of the outer surface 10o of the crucible base body 10 is lower than a fictive temperature T₂ (° C.) of the inside of the base body, which is at a depth of 5 mm from the outer surface 10o, by 50° C. or more (T₁<T₂−50). In a case where the fictive temperature T₁ of the outer surface 10o of the crucible base body 10 is equivalent to or slightly lower than the fictive temperature T₂ inside the crucible base body 10, diffusion of the crystallization accelerator or substitution of the Si—O bond is unlikely to occur, and an outer surface crystal layer having a sufficient thickness to the extent that a desired crucible strength can be exhibited in the initial stage of heating cannot be obtained. However, in a case where the fictive temperature T₁ of the outer surface 10o of the crucible base body 10 is lower than the fictive temperature T₂ inside the crucible base body 10 by 50° C. or more, the Si—O bond is more likely to be broken in the outer surface 10o as compared with in the inside of the crucible base body 10, diffusion of the crystallization accelerator or substitution of the Si—O bond is likely to occur, and the effect of promoting crystallization is exhibited.

The fictive temperature of the silica glass constituting the crucible base body 10 can be measured by a Raman spectroscopic analysis method or an FT-IR method. In the Raman spectroscopic analysis method, an area intensity ratio of a peak derived from a 3-membered ring, which is a cyclic structure of Si, and a peak derived from a 4-membered ring is obtained from a Raman (scattering) spectrum in a case where a sample surface to be measured is irradiated with laser light. The obtained result is plotted on a calibration curve obtained from the sample measurement with a known fictive temperature, whereby the fictive temperature of the corresponding sample can be calculated.

In a case of the fictive temperature measurement by the FT-IR method, a peak wavelength derived from a quartz glass structure is detected from a transmission spectrum in a case where a sample obtained by thinning glass to be measured is irradiated with laser light. The obtained result is plotted on a calibration curve obtained from the sample measurement with a known fictive temperature, whereby the fictive temperature of the corresponding sample can be calculated.

A crystallization accelerator-containing coating film 13 is provided on the outer surface 10o of the crucible base body 10. The crystallization accelerator contained in the crystallization accelerator-containing coating film 13 accelerates crystallization of the outer surface of the crucible at high temperature during the single crystal pulling up step and thus the strength of the crucible can be improved. In this example, the reason why the crystallization accelerator-containing coating film 13 is provided on the outer surface side of the crucible is as follows. First, In a case where the crystallization accelerator-containing coating film 13 is provided on the inner surface side of the crucible, the risk of pinhole formation in the silicon single crystal and the risk of peeling of the outer layer on the inner surface of the crucible increase, but such a risk can be reduced in a case where the crystallization accelerator-containing coating film 13 is provided on the outer surface side of the crucible. In addition, in a case where the crystallization accelerator-containing coating film 13 is provided on the inner surface of the crucible, there is a risk of contamination of the single crystal due to contamination of the inner surface of the crucible with impurities, but since the contamination of the outer surface of the crucible with impurities is allowed to some extent, the risk of contamination of the single crystal due to the provision of the crystallization accelerator-containing coating film 13 on the outer surface of the crucible is low.

In the present embodiment, the crystallization accelerator-containing coating film 13 is provided in the entire crucible from the sidewall 10a to the bottom 10b, but the crystallization accelerator-containing coating film 13 may be provided at least in the sidewall 10a. This is because the sidewall 10a is more easily deformed than the corner 10c and the bottom 10b, and the effect of suppressing deformation of the crucible by crystallization of the outer surface is large. It is preferable that the crystallization accelerator-containing coating film 13 is provided not only on the sidewall 10a but also on the corner 10c. The crystallization accelerator-containing coating film 13 may or may not be provided on the bottom 10b of the crucible. This is because the bottom 10b of the crucible receives a large amount of weight of the silicon melt and thus easily adapts to the carbon susceptor, and a gap is not easily formed between with the carbon susceptor.

The upper end portion of the rim, which is 1 to 3 cm below the upper edge of the rim, on the outer surface of sidewall 10a of the crucible may be a region in which the crystallization accelerator-containing coating film 13 is not formed. As a result, crystallization of the upper end surface of the rim can be suppressed, and dislocation in the silicon single crystal due to mixing of the crystal pieces peeled from the upper end surface of the rim into the silicon melt can be prevented.

The crystallization accelerator contained in the crystallization accelerator-containing coating film 13 is preferably barium (Ba) or strontium (Sr), and particularly preferably Ba. This is because Ba has a smaller segregation coefficient than silicon, is stable at room temperature, and is easy to handle. In addition, Ba has an advantage that the crystallization rate of the crucible is not attenuated with crystallization and orientation growth is induced more strongly than other elements.

The crystallization accelerator-containing coating film 13 contains barium carbonate and a thickener, and the concentration of Ba contained in the crystallization accelerator-containing coating film 13 is preferably 1.0×10¹⁵ to 1.0×10¹⁸ atoms/cm² and particularly preferably 1.0×10¹⁶ to 1.0×10¹⁷ atoms/cm². In a case where the concentration of Ba is lower than 1.0×10¹⁵ atoms/cm², unevenness occurs in the thickness and the crystallization range of the outer surface crystal layer, and there is a concern that an outer surface crystal layer having a sufficient thickness for achieving an improvement of the strength is not formed. In addition, in a case where the concentration of Ba is higher than 1.0×10¹⁸ atoms/cm², the probability of occurrence of cracks in the outer surface crystal layer increases because of excessive progress of crystallization of the outer surface. However, in a case where the Ba concentration is within the above-described range, such an issue can be avoided, and crystallization of the outer surface can be promoted while suppressing foaming-related peeling of the outer surface crystal layer.

The thickness of the crystallization accelerator-containing coating film 13 is not particularly limited, but is preferably 0.1 to 50 μm and particularly preferably 1 to 20 μm. This is because in a case where the thickness of the crystallization accelerator-containing coating film 13 is too thin, the peel strength of the crystallization accelerator-containing coating film 13 is weak, and the peeling of the coating film causes nonuniform crystallization. Also in a case where the coating film is too thick, the peel strength is lowered and the crystallization is nonuniform.

In a case where the quartz glass crucible 1 according to the present embodiment is heat-treated in a furnace at 1580° C. and 20 Torr and in an Ar atmosphere, a length of crystal growth (a length of crystallization) that proceeds from the outer surface 10o of the crucible base body 10 in a depth direction is 0.21 to 0.5 mm from the start of the heat treatment to 10 hours later. That is, the thickness of the outer surface crystal layer formed on the outer surface 10o of the crucible base body 10 after 10 hours is 210 to 500 μm. In addition, the crystallization rate 10 hours after the start of the heat treatment is 21 to 50 μm/hr, but the crystallization rate after 20 hours from the start of the heat treatment is 10 μm/hr or less. In a case where the crystallization rate of the outer surface is higher than 50 μm/hr in the initial stage of crystallization, there is a risk of foaming-related peeling of the outer surface crystal layer. In addition, in a case where the crystallization rate is lower than 21 μm/hr, the crystallization of the outer surface is insufficient, and the desired strength of the crucible cannot be developed. However, according to the present invention, it is possible to form an outer surface crystal layer having a sufficient thickness without causing foaming-related peeling of the outer surface crystal layer, and to develop a desired strength of the crucible.

In this example, “10 hours later” from the start of the heat treatment means a timing at which all the polycrystalline silicon raw materials in the crucible are dissolved and a stress begins to be applied also to the crucible wall portion. This is because the probability that the crucible is deformed increases in a case where the timing at which the outer surface crystal layer has a sufficient thickness is later than this. In addition, the crystallization rate 10 hours after the start of the heat treatment is a value obtained by dividing the thickness of the outer surface crystal layer 10 hours later by the heat treatment time (10 hours), and is obtained as an average value of the crystallization rate for 10 hours. Furthermore, the crystallization rate after 20 hours from the start of the heat treatment is a value obtained by dividing the difference between the thickness of the outer surface crystal layer 20 hours later and the thickness of the outer surface crystal layer 30 hours later by the heat treatment time (10 hours), and is obtained as an average value of the crystallization rate for 10 hours.

Furthermore, as described above, it is preferable that the crystallization rate decreases 15 hours after the start of the heat treatment, and the crystallization rate after 20 hours from the start of the heat treatment is 10 μm/hr or less. In a case where the crystallization rate after 20 hours from the start of the heat treatment is higher than 10 μm/hr, the thickness of the outer surface crystal layer is too thick, and there is a risk that the crystal layer may be broken during crystal pulling. The crystallization rate is lowered after the melting of the polycrystalline raw material, whereby not only the strength of the crucible can be developed at an early stage, but also the strength can be maintained.

The thickness of the outer surface crystal layer formed on the outer surface 10o of the crucible base body 10 25 hours after the start of the heat treatment at 1580° C. is preferably about 210 to 600 μm and particularly preferably 210 to 500 μm. In a case where the thickness of the outer surface crystal layer after 25 hours from the start of the single crystal pulling up step is less than 210 μm, the probability of deformation of the crucible due to insufficient strength increases. In addition, in a case where the thickness of the outer surface crystal layer is more than 500 μm, the adhesiveness between the crucible and the carbon susceptor is deteriorated, and the thermal conductivity between the carbon susceptor and the quartz glass crucible fluctuates during the crystal pulling up step, thereby adversely affecting the control of the oxygen concentration and the crystal diameter of the silicon single crystal. In addition, in a case where the outer surface crystal layer is too thick, the outer surface crystal layer is subjected to foaming-related peeling, which adversely affects the pulling up of the single crystal. However, in a case where the thickness of the crystal layer is within the above-described range, the strength can be developed after the crucible has been adapted to the carbon susceptor, and the oxygen concentration and the crystal diameter of the silicon single crystal can be stably controlled.

In a quartz glass crucible in which a crystallization accelerator is applied onto an outer surface, it is considered that the concentration of the crystallization accelerator determines the final thickness of the outer surface crystal layer. By increasing the concentration of the crystallization accelerator, a thick outer surface crystal layer can be formed. However, in a case where the concentration of the crystallization accelerator is increased, the crystallization of the outer surface is promoted not only in the depth direction but also in the plane direction. Therefore, the outer surface crystal layer is likely to be subjected to foaming-related peeling or cracked.

In the crystallization of the outer surface of the crucible, first, dot-like crystal nuclei (embryonic nuclei) is generated. The crystal nuclei grow with the passage of the heating time, and in the process, the crystal nuclei merge with another crystal nucleus in the vicinity to form a sheet-like crystal layer. It is ideal that the sheet-like crystal layer thickens without being peeled off. However, in a case where the time until the crystal layer reaches the strength development level is too short, foaming-related peeling or cracks are likely to occur, and conversely, in a case where crystallization is too slow, the crucible is deformed before the strength is developed. So far, the crystallization rate cannot be optimized only by increasing the concentration of the crystallization accelerator.

On the other hand, in the quartz glass crucible according to the present embodiment, elements other than the concentration of the crystallization accelerator, that is, the fictive temperature gradient in the depth direction from the outer surface or the concentration of metal impurities such as Ca and Fe are adjusted to promote the crystallization in the depth direction of the outer surface, thereby attempting optimization of the crystallization rate. Therefore, it is possible to increase the strength of the crucible by forming an outer surface crystal layer having a sufficient thickness while preventing the occurrence of foaming-related peeling or cracks.

Next, the method for producing the quartz glass crucible 1 will be described. The quartz glass crucible 1 according to the present embodiment can be manufactured by applying a crystallization accelerator to the outer surface 10o of the crucible base body 10 after manufacturing the crucible base body 10 by a so-called rotational molding method.

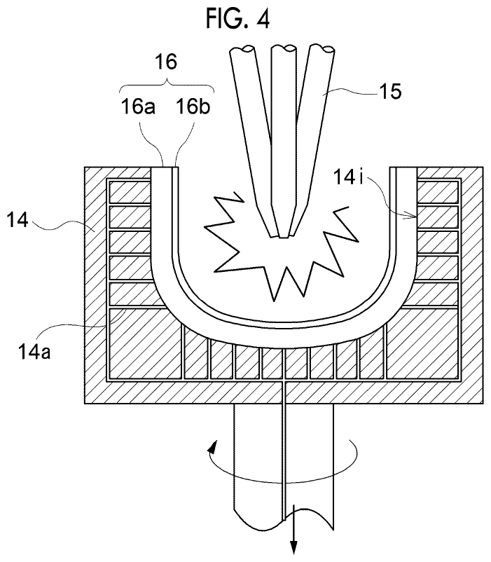

FIG. 4 is a schematic diagram illustrating a manufacturing method of the quartz glass crucible according to a rotational molding method.

As shown in FIG. 4, In the rotational molding method, a carbon mold 14 having a cavity matching the outer shape of the crucible is prepared, and the natural quartz powder 16a and the synthetic quartz powder 16b are sequentially filled along the inner surface 14i of the rotating carbon mold 14 to form a deposited layer 16 of raw material quartz powders. The raw material quartz powders stay in a fixed position while sticking to the inner surface 14i of the carbon mold 14 by centrifugal force, and are maintained in a crucible shape.

Next, the arc electrode 15 made of carbon is installed in the carbon mold 14, and a deposited layer 16 of the raw material quartz powders is arc-melted from the inside of the carbon mold 14. Specific conditions such as heating time and heating temperature are appropriately determined in consideration of the properties of the raw material quartz powders, the size of the crucible, and the like.

During the arc melting, the amount of bubbles in the molten quartz glass is controlled by evacuating the deposited layer 16 of the raw material quartz powders from a large number of vent holes 14a provided in the inner surface 14i of the carbon mold 14. Specifically, at the start of arc melting, the deposited layer 16 of the raw material quartz powders is evacuated to form the transparent layer 11, and after the formation of the transparent layer 11, the evacuating of the raw material quartz powders is stopped or the suction force is reduced to form the bubble layer 12.

Since the arc heat is transferred from the inside to the outside of the deposited layer 16 of the raw material quartz powders to melt the raw material quartz powders, by changing decompression conditions at the timing at which the raw material quartz powders start to melt, the transparent layer 11 and the bubble layer 12 can be made separately. That is, in a case where decompression melting for strengthening the decompression is performed at the timing at which raw material quartz powders melt, atmosphere gas is not trapped in the glass, and thus the molten quartz becomes silica glass containing no bubbles. In addition, in a case where normal melting (atmospheric pressure melting) for weakening the decompression is performed at the timing at which raw material quartz powders melt, atmosphere gas is trapped in the glass, and thus the molten quartz becomes silica glass containing a large number of bubbles.

To make the Al concentration in the first depth region within 10 mm from the outer surface 10o of the crucible base body 10 higher than the Ca and Fe concentrations, it is preferable to use the carbon mold 14 having a high Al impurity concentration on the inner surface and to diffuse Al to the region that becomes the outer surface 10o of the crucible base body 10 during arc melting. Alternatively, in a case where the carbon mold 14 is filled with the quartz raw material powders, outside from a region of the outer surface 10o of the crucible base body 10 may be filled with a raw material having a high Al impurity concentration after arc melting, and Al may be diffused to the region that becomes the outer surface 10o of the crucible base body 10 during arc melting. In addition, the raw material having a high concentration of Al impurities may be removed after the arc melting. In both methods, the Al concentration can be increased and the Ca and Fe concentrations can be decreased in the vicinity of the outer surface 10o of the crucible base body 10, whereby the crystallization in the thickness direction can be promoted as compared with the in-plane direction.

The fictive temperature changes depending on the cooling temperature of the glass. In a case where the molten quartz is rapidly cooled, the fictive temperature of the quartz glass is increased, and in a case where the molten quartz is slowly cooled, the fictive temperature of the quartz glass is decreased. Since the arc electrode 15 serving as a heat source during arc melting is located on the inner surface side of the crucible, the cooling of the inner surface of the crucible is started immediately after the arc ends. On the other hand, the carbon mold 14 is present on the outer surface side of the crucible, and the carbon mold maintains a high temperature state even after the arc ends. In this example, by temporarily stopping the air cooling or water cooling of the carbon mold 14, the cooling rate on the outer surface 10o side of the crucible base body 10 is lower than that on the inner surface 10i side. That is, since the outer surface 10o side of the crucible base body 10 is slowly cooled than the inner surface 10i side, the fictive temperature of the outer surface 10o is lower than that of the inside. In the present embodiment, the heat retention property is further enhanced by heating the carbon mold 14 or the like, and the cooling rate on the outer surface 10o side of the crucible base body 10 is further reduced, whereby the fictive temperature difference between the outer surface 10o of the crucible base body 10 and the inside of the base body is increased to 50° C. or more.

Subsequently, the arc melting is terminated and the crucible is cooled. As described above, the crucible base body 10 is completed, in which the transparent layer 11 and the bubble layer 12 are provided in that order from the inside toward the outside of the crucible wall. As described above, the crucible base body 10 according to the present embodiment can be manufactured by filling the carbon mold 14 which is rotated with the natural quartz powder 16a as an outer layer raw material, filling the carbon mold 14 with the synthetic quartz powder 16b as an inner layer raw material, and arc-melting the deposited layer 16 of the raw material quartz powders.

Next, the shape of the crucible base body 10 is adjusted by cutting the rim portion, or the like, then cleaned with a cleaning liquid, and further rinsed with pure water. The cleaning liquid is preferably prepared by diluting hydrofluoric acid of semiconductor grade or higher with pure water of TOC≤2 ppb to adjust to 10 to 40 w %.

Next, the crystallization accelerator is applied to the outer surface 10o of the crucible base body 10. It is preferable that a brush is used for the application of the coating liquid. To uniformly disperse the crystallization accelerator on the outer surface 10o, a coating liquid is preferably used, in which the crystallization accelerator is dissolved in pure water (15° C. to 25° C., 17.2 MΩ or more, and TOC≤2 ppb). To increase the solubility of the crystallization accelerator, it is preferable to stir the coating liquid using a stirrer.

In a case where the crystallization accelerator is, for example, barium, a solution containing a barium compound such as barium carbonate can be used. The coating liquid containing a barium compound may be a coating liquid consisting of a barium compound and water, or may be a coating liquid containing absolute ethanol and a barium compound without containing water. As the barium compound, barium carbonate is preferable, but other barium compounds such as barium chloride, barium acetate, barium nitrate, barium hydroxide, barium oxalate, and barium sulfate may be used. It should be noted that in a case where the surface concentration (atoms/cm²) of the barium element is the same, the effect of accelerating crystallization is the same regardless of whether it is insoluble or water-soluble, but the barium insoluble in water is more difficult to be taken in human body, and thus is highly safe and advantageous in terms of handling.

The coating liquid containing the barium compound preferably further contains a highly viscous water-soluble polymer (thickener) such as carboxyvinyl polymer. In a case where a coating liquid that does not contain a thickener is used, the fixation of barium to the crucible wall surface is unstable, and thus heat treatment is required to fix the barium. Barium diffuses and penetrates into the interior of the quartz glass by performing such heat treatment, which is a factor that promotes the random growth of crystals. In this example, random growth means a growth that has no regularity in the crystal growth direction in the crystal layer and in which crystals grow in all directions. In random growth, crystallization stops at the initial stage of heating, and thus a sufficient thickness of the crystal layer cannot be secured.

However, in the case of using a coating liquid containing a thickener together with the barium compound, the viscosity of the coating liquid increases and thus non-uniformity by flowing of the coating liquid due to gravity or the like when the coating liquid is applied to the crucible can be prevented. In addition, in a case where the coating liquid of a barium compound such as barium carbonate contains a water-soluble polymer, the barium compound is dispersed in the coating liquid without aggregating, and thus the barium compound can be uniformly applied to the crucible surface. Therefore, high-concentration barium can be uniformly and densely fixed on the crucible wall surface, and the growth of crystal grains in columnar orientation or dome-shaped orientation can be promoted.

A columnar-oriented crystal refers to a crystal layer composed of an aggregate of columnar crystal grains. A dome-shaped oriented crystal refers to a crystal layer composed of an aggregate of dome-shaped crystal grains. A columnar orientation or a dome-shaped orientation can sustain crystal growth, and thus a crystal layer having a sufficient thickness can be formed.

Examples of thickener can include water-soluble polymers containing little metal impurities, such as polyvinyl alcohol, cellulose-based thickeners, high-purity glucomannan, acrylic polymers, carboxyvinyl polymers, and polyethylene glycol fatty acid esters. In addition, an acrylic acid-alkyl methacrylate copolymer, polyacrylate, polyvinylcarboxylic acid amide, vinylcarboxylic acid amide, or the like may be used as a thickener. The viscosity of the coating liquid containing barium is preferably in the range of 100 to 10000 mPa s, and the boiling point of the solvent is preferably in the range of 50° C. to 100° C.

For example, a crystallization accelerator coating liquid for coating the outer surface of a 32-inch crucible contains 0.0012 g/mL of barium carbonate and 0.0008 g/mL of carboxyvinyl polymer, and can be prepared by adjusting the ratio of ethanol and pure water and mixing and stirring them.

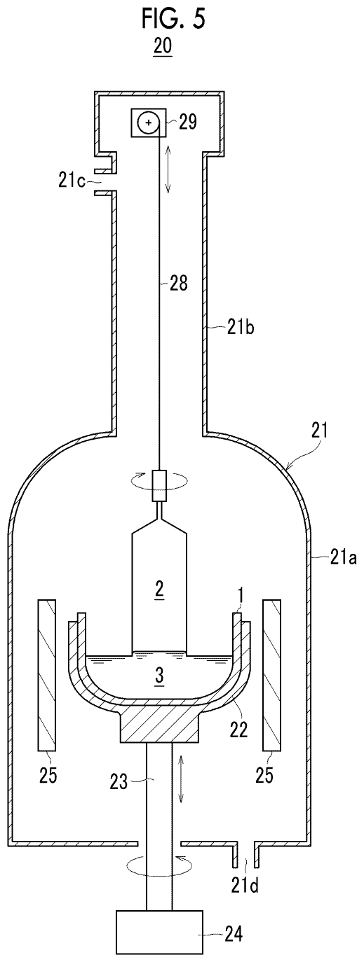

FIG. 5 is a diagram for explaining a single crystal pulling up step using the quartz glass crucible 1 according to the present embodiment, and is a schematic sectional view illustrating the configuration of a single crystal pulling apparatus.

As shown in FIG. 5, a single crystal pulling apparatus 20 is used for the pulling up step of a silicon single crystal by the CZ method. The single crystal pulling apparatus 20 includes a water-cooled chamber 21, a quartz glass crucible 1 holding a silicon melt in the chamber 21, a carbon susceptor 22 holding the quartz glass crucible 1, a rotating shaft 23 supporting the carbon susceptor 22 to be capable of rotation and elevation, a shaft driving mechanism 24 that rotates and elevation-drives the rotating shaft 23, a heater 25 that is arranged around the carbon susceptor 22, a single crystal pulling-up wire 28 that is arranged above the quartz glass crucible 1 and on the same axis with the rotating shaft 23, and a wire winding mechanism 29 arranged above the chamber 21.

The chamber 21 is configured by a main chamber 21a and a slender cylindrical pull chamber 21b which is connected to an upper opening of the main chamber 21a. The quartz glass crucible 1, the carbon susceptor 22, and the heater 25 are provided in the main chamber 21a. A gas entry 21c for introducing inert gas (purge gas) such as argon gas or a dopant gas into the main chamber 21a is provided in the upper portion of the pull chamber 21b, and a gas outlet 21d for discharging atmospheric gas inside the main chamber 21a is provided in the lower portion of the main chamber 21a.

The carbon susceptor 22 is used to hold the shape of the quartz glass crucible 1 which is softened at high temperature, and holds the quartz glass crucible 1 to wrap around it. The quartz glass crucible 1 and the carbon susceptor 22 configure a double-structured crucible that supports the silicon melt in the chamber 21.

The carbon susceptor 22 is fixed to the upper end of the rotating shaft 23, and the lower end of the rotating shaft 23 passes through the bottom of the chamber 21 and is connected to a shaft driving mechanism 24 provided outside of the chamber 21.

The heater 25 is used to melt the polycrystalline silicon raw material filled in the quartz glass crucible 1 to generate the silicon melt 3, as well as to keep a molten state of the silicon melt 3. The heater 25 is a resistance heating type carbon heater, and is provided surrounding the quartz glass crucible 1 in the carbon susceptor 22.

The wire winding mechanism 29 is arranged above the pull chamber 21b, the wire 28 extends downward from the wire winding mechanism 29 passing through the interior of the pull chamber 21b, and a distal end of the wire 28 reaches the inner space of the main chamber 21a. This figure shows a state in which the silicon single crystal 2 in the middle of growth is suspended on the wire 28.

When the silicon single crystal 2 is pulled up, the wire 28 is gradually pulled up while rotating the quartz glass crucible 1 and the silicon single crystal 2 individually to grow the silicon single crystal 2. Although the amount of the silicon melt in the quartz glass crucible 1 decreases as a silicon single crystal 2 grows, the quartz glass crucible 1 is raised such that the height of the melt surface is constant. In this manner, it is possible to attempt an stabilization of the crystal quality in the crystal growth direction.

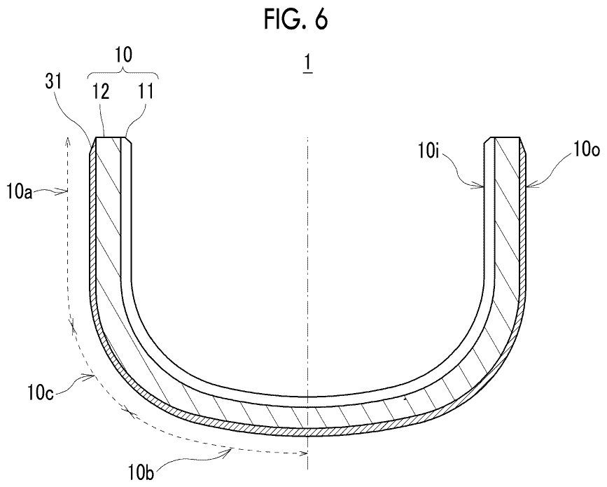

FIG. 6 is a schematic side sectional view illustrating a crystallization state of the quartz glass crucible by heating.

As shown in FIG. 6, an outer surface crystal layer 31 is formed on the outer surface 10o of the quartz glass crucible 1 in the crystal pulling up step. The Ba concentration in the outer surface crystal layer 31 formed on the outer surface 10o of the crucible base body 10 by heating during the crystal pulling up step or a heat treatment equivalent thereto is preferably less than 10 ppm. In a case where the Ba concentration in the outer surface crystal layer 31 is 10 ppm or more, since the concentration of the crystallization accelerator applied onto the outer surface 10o of the crucible base body 10 is high, the crystallization of the outer surface 10o is excessively promoted, and the outer surface crystal layer 31 is likely to be subjected to foaming-related peeling. However, in a case where the Ba concentration in the outer surface crystal layer 31 is less than 10 ppm, it is possible to promote the crystallization of the outer surface while suppressing foaming-related peeling of the outer surface crystal layer 31.

As described above, the quartz glass crucible 1 according to the present embodiment includes the crucible base body 10 made of silica glass and the crystallization accelerator-containing coating film 13, which is formed on the outer surface 10o of the crucible base body 10, in which 10 hours after the start of a heat treatment, the length of the crystal growth that proceeds from the outer surface 10o of the crucible base body 10 in the depth direction is 0.21 to 0.5 mm and the crystallization rate is 21 to 50 μm/hr, and the crystallization rate of the outer surface 10o after 20 hours from the start of the heat treatment is 10 μm/hr or less, the heat treatment being performed in the furnace at a furnace temperature of 1580° C. and a furnace pressure of 20 Torr, and in an Ar atmosphere. Therefore, it is possible to form the outer surface crystal layer 31 having a sufficient thickness of 200 μm or more on the outer surface of the crucible at a high temperature in the pulling up step of the silicon single crystal, and it is possible to make the crystallization of the outer surface 10o proceed at an appropriate rate, neither too fast nor too slow. Therefore, it is possible to form an outer surface crystal layer 31 having a sufficient thickness while preventing foaming-related peeling of the outer surface crystal layer 31, and to impart a desired strength to the crucible.

In addition, in the quartz glass crucible 1 according to the present embodiment, since the fictive temperature of the outer surface 10o of the crucible base body 10 is lower than the fictive temperature of the inside at a depth position of 5 mm from the outer surface 10o by 50° C., the crystallization of the outer surface of the crucible can be promoted, and the crystallization of the outer surface of the crucible is not too fast or too slow and has an appropriate strength development time. Therefore, it is possible not only to withstand a long-duration single crystal pulling up step but also to minimize the gap between the crucible and the carbon susceptor, thereby stably controlling the oxygen concentration and the crystal diameter of the silicon single crystal.

Although preferred embodiments of the present invention were described above, the present invention is not limited to the above-described embodiments, and various modifications can be added without departing from the scope of the present invention, and such modifications are, needless to say, covered by the scope of the present invention.

### Examples

Four crucible base bodies having different concentrations of metal impurities on an outer surface were prepared, a part of the outer surface of the crucible base body was coated with a barium carbonate solution with a brush, and then the crucible was crushed and fragmented. Among a plurality of crucible pieces obtained from the same crucible base body, those not coated with barium carbonate were used to perform the metal impurity analysis in the depth direction from the outer surface of the crucible base body. In the metal impurity analysis, silica glass at a certain depth from the outer surface of the crucible was dissolved by wet etching, the etchant was recovered, and the amount of metal impurities dissolved in the etchant was measured by inductively coupled plasma-mass spectrometry (ICP-MS).

In the measurements of Al, Ca, and Fe among the metal impurities, a depth region from the outer surface of the crucible base body to 5 mm was set as a measurement range of the first measurement, a depth region of 5 to 10 mm from the inner surface of the crucible base body was set as a measurement range of the second measurement, and a depth region of 10 to 15 mm from the inner surface of the crucible base body was set as a measurement range of the third measurement. The measurement results are shown in Tables 1 and 2.

TABLE 1

| | Outer surface | | | | | |
|---|---|---|---|---|---|---|
| | to 5 mm | | 5 to 10 mm | | 10 to 15 mm | |
| | Fe | Al | Fe | Al | Fe | Al |
| | concen- | concen- | concen- | concen- | concen- | concen- |
| | tration | tration | tration | tration | tration | tration |
| | (ppm) | (ppm) | (ppm) | (ppm) | (ppm) | (ppm) |
| Comparative | 1 | 0.5 | 1 | 0.5 | 1 | 0.5 |
| Example1 | | | | | | |
| Comparative | 1 | 10 | 1 | 0.5 | 1 | 0.5 |
| Example2 | | | | | | |
| Example1 | 1 | 10 | 1 | 10 | 1 | 0.5 |
| Example2 | 1 | 10 | 1 | 10 | 1 | 10 |

As shown in Table 1, in the Fe and Al concentration profiles of the crucible base body of Comparative Example 1, the Fe concentration was higher in the entire region from the outer surface to 15 mm in the depth direction, and a relationship of Fe concentration>Al concentration was established. In addition, in the Fe and Al concentration profiles of the crucible base body of Comparative Example 2, a relationship of Fe concentration<Al concentration was established in a depth region from the outer surface to 5 mm, and a relationship of Fe concentration>Al concentration was established in a depth region of 5 to 15 mm. On the other hand, in the Fe and Al concentration profiles of the crucible base body of Example 1, a relationship of Fe concentration<Al concentration was established in a depth region from the outer surface to 10 mm, and a relationship of Fe concentration>Al concentration was established in a depth region of 10 to 15 mm. Furthermore, in the crucible base body of Example 2, a relationship of Fe concentration<Al concentration was established in the entire region of the depth direction from the outer surface to 15 mm.

TABLE 2

| | Outer surface | | | | | |
|---|---|---|---|---|---|---|
| | to 5 mm | | 5 to 10 mm | | 10 to 15 mm | |
| | Ca | Al | Ca | Al | Ca | Al |
| | concen- | concen- | concen- | concen- | concen- | concen- |
| | tration | tration | tration | tration | tration | tration |
| | (ppm) | (ppm) | (ppm) | (ppm) | (ppm) | (ppm) |
| Comparative | 1 | 0.5 | 1 | 0.5 | 1 | 0.5 |
| Example1 | | | | | | |
| Comparative | 1 | 10 | 1 | 0.5 | 1 | 0.5 |
| Example2 | | | | | | |
| Example1 | 1 | 10 | 1 | 10 | 1 | 0.5 |
| Example2 | 1 | 10 | 1 | 10 | 1 | 10 |

As shown in Table 2, the Ca concentration profile also had the same tendency as Fe concentration profile. That is, in the Ca and Al concentration profiles of the crucible base body of Comparative Example 1, the Ca concentration was higher in the entire region from the outer surface to 15 mm in the depth direction, and the relationship of Ca concentration>Al concentration was established. In addition, in the Ca and Al concentration profiles of the crucible base body of Comparative Example 2, a relationship of Ca concentration<Al concentration was established in a depth region from an outer surface to 5 mm, and a relationship of Ca concentration>Al concentration was established in a depth region of 5 to 15 mm. On the other hand, in the Ca and Al concentration profiles of the crucible base body of Example 1, a relationship of Ca concentration<Al concentration was established in a depth region from the outer surface to 10 mm, and a relationship of Ca concentration>Al concentration was established in a depth region of 10 to 15 mm. Furthermore, in the crucible base body of Example 2, a relationship of Ca concentration<Al concentration was established in the entire region of the depth direction from the outer surface to 15 mm.

As described above, in the crucible samples of Comparative Examples 1 and 2, the Fe concentration and the Ca concentration in the depth region from the outer surface to 10 mm were higher than the Al concentration, whereas in the crucible samples of Examples 1 and 2, the Al concentration in the depth region from the outer surface to 10 mm was lower than the Fe concentration and the Ca concentration.

In the measurement of B, Mg, and Cr among the metal impurities, a depth region from the outer surface to two-thirds of the wall thickness of the crucible was set as a measurement range, the silica glass was dissolved by wet etching, the etchant was recovered, and the amount of the metal impurities dissolved in the etchant was measured by ICP-MS. The measurement results are shown in Table 3.

TABLE 3

| | B concentration | Mg concentration | Cr concentration |
|---|---|---|---|
| | (ppm) | (ppm) | (ppm) |
| Comparative | 0.1 | 0.5 | 0.1 |
| Example1 | | | |
| Comparative | 0.01 | 0.01 | 0.01 |
| Example2 | | | |
| Example1 | 0.02 | 0.02 | 0.02 |
| Example2 | 0.05 | 0.4 | 0.08 |

As shown in Table 3, the B concentration of the crucible base body of Comparative Example 1 was 0.1 ppm. The B concentration of the crucible base body of Comparative Example 2 was 0.01 ppm. On the other hand, the B concentration profile of the crucible base body of Example 1 was 0.02 ppm, and the B concentration of the crucible base body of Example 2 was 0.05 ppm.

In addition, as shown in Table 3, the Mg concentration of the crucible base body of Comparative Example 1 was 0.5 ppm. The Mg concentration of the crucible base body of Comparative Example 2 was 0.01 ppm. On the other hand, the Mg concentration profile of the crucible base body of Example 1 was 0.02 ppm, and the Mg concentration of the crucible base body of Example 2 was 0.4 ppm.

In addition, as shown in Table 3, the Cr concentration of the crucible base body of Comparative Example 1 was 0.1 ppm. The Mg concentration of the crucible base body of Comparative Example 2 was 0.01 ppm. On the other hand, the Cr concentration of the crucible base body of Example 1 was 0.02 ppm, and the Cr concentration of the crucible base body of Example 2 was 0.08 ppm.

Next, a fictive temperature of the outer surface of the crucible base body and a fictive temperature of the inside of the base body at a depth position of 5 mm from the outer surface were measured by a Raman spectroscopic analysis method. The measurement region of the fictive temperature of the outer surface was set to a range of a depth of 0 mm to 0.5 mm from the outer surface. In addition, the measurement region of the fictive temperature inside the base body was set to a range of a depth of 5.0 mm to 5.5 mm from the outer surface. Table 4 shows the fictive temperature difference between the outer surface and the inside of the crucible base body.

TABLE 4

| | Fictive temperature | | | | | |
|---|---|---|---|---|---|---|
| | difference between | | Crystallization | Strength | | |
| | outer surface and inside | | rate | development | | |
| | (° C.) | | (μm/hr) | effect | Deformation | Peeling |
| Comparative | +10° | C. | 0.5 | Absent | Absent | Present |
| Example1 | | | | | | |
| Comparative | 0 | | 1 | Absent | Present | Absent |
| Example2 | | | | | | |
| Example1 | ▴50° | C. | 21 | Present | Absent | Absent |
| Example2 | ▴100° | C. | 50 | Present | Absent | Absent |

Next, a heating test was performed using the crucible piece coated with barium carbonate. In the heating test, a crucible piece having one side of 10 to 20 cm and an area of 200 cm² or more and having an aspect ratio as close to 1 as possible was used. As heating conditions, the temperature of the furnace in an Ar atmosphere was raised from room temperature to 1580° C. over 2.5 hours, and then 1580° C. was held for 10 hours. The pressure in the furnace held at 1580° C. was set to 20 Torr.

Thereafter, the crystallization state of the outer surface of the crucible piece was evaluated. Specifically, the thickness of the outer surface crystal layer of the crucible piece was obtained, and the ratio of the thickness of the outer surface crystal layer to the high temperature holding time (10 hr) of 1580° C. was obtained as the crystallization rate. In addition, it was determined that the crucible piece in which the thickness of the outer surface crystal layer was 200 μm or more had the strength development effect, and the crucible piece in which the thickness was less than 200 μm had no strength development effect.

As a result, as shown in Table 4, in the crucible samples of Comparative Examples 1 and 2, the fictive temperature difference was 10° C. or less, the crystallization rate was 1 μm/hr or less, and the strength development effect was not obtained. On the other hand, in the crucible samples of Examples 1 and 2, the fictive temperature difference was 50° C. or more, the crystallization rate was 21 μm/hr or more, and the strength development effect was obtained. From the above results, it was found that in a case where the fictive temperature difference was 50° C. or higher, an outer surface crystal layer having a thickness of 200 μm or more could be formed on the outer surface of the crucible, and the strength development effect could be obtained.

Silicon single crystals were actually pulled up using another crucible produced under the same conditions as in Examples 1 and 2 and Comparative Examples 1 and 2, and the state of deformation and peeling of the crucible was visually confirmed. Table 4 also shows the results of deformation and peeling of the crucible. In this example, the “deformation” is a result of evaluation by visual observation of whether or not deformation such as inward deformation of the opening portion, buckling of the corner from the sidewall, and unevenness of the surface caused by the adaptation to the carbon susceptor occurs with respect to the crucible before use. In addition, the “peeling” is a result of evaluation by visual observation of whether or not a part of the crystal layer formed on the outer surface of the crucible is peeled off by foaming, deformation, or the like, and an uncrystallized glass surface is exposed.

As shown in Table 4, in the quartz glass crucible of Comparative Example 1, peeling of the crystal layer was observed. In addition, in the quartz glass crucible of Comparative Example 2, deformation was observed. However, in the quartz glass crucible of Examples 1 and 2, neither deformation nor peeling occurred.

### DESCRIPTION OF REFERENCE NUMERALS

1 Quartz glass crucible
2 Silicon single crystal
3 Silicon melt
10 Crucible base body
10a Sidewall
10b Bottom
10c Corner
10i Inner surface
10o Outer surface
11 Transparent layer
12 Bubble layer
13 Crystallization accelerator-containing coating film
14 Carbon mold
14a Vent hole
14i Inner surface of carbon mold
15 Arc electrode
16 Deposited layer of raw material quartz powders
16a Natural quartz powder
16b Synthetic quartz powder
20 Single crystal pulling apparatus
21 Chamber
21a Main chamber
21b Pull chamber
21c Gas entry
21d Gas outlet
22 Carbon susceptor
23 Rotating shaft
24 Shaft driving mechanism
25 Heater
28 Wire
29 Wire winding mechanism
31 Outer surface crystal layer
D1 First depth region
D2 Second depth region
D3 Third depth region

1. A quartz glass crucible comprising:
a crucible base body made of silica glass; and
a crystallization accelerator-containing coating film formed on an outer surface of the crucible base body,
wherein, 10 hours after a start of a heat treatment performed in an Ar atmosphere at a furnace temperature of 1580° C. and a furnace pressure of 20 Torr, a thickness of an outer surface crystal layer formed on the outer surface of the crucible base body is 0.21 to 0.5 mm and a crystallization rate is 21 to 50 μm/hr, and
a crystallization rate of the outer surface after 20 hours from the start of the heat treatment is 10 μm/hr or less.

2. The quartz glass crucible according to claim 1,
wherein a fictive temperature of the outer surface of the crucible base body is lower than a fictive temperature of an inside of the base body at a depth of 5 mm from the outer surface by 50° C. or more.

3. The quartz glass crucible according to claim 1,
wherein an Al concentration in a first depth region within 10 mm from the outer surface of the crucible base body is higher than an Fe concentration in the first depth region.

4. The quartz glass crucible according to claim 1,
wherein an Al concentration in a first depth region within 10 mm from the outer surface of the crucible base body is higher than a Ca concentration in the first depth region.

5. The quartz glass crucible according to claim 1,
wherein the crystallization accelerator is Ba, and a Ba concentration in an outer surface crystal layer formed on the outer surface of the crucible base body after the heat treatment is less than 10 ppm.

6. The quartz glass crucible according to claim 1,
wherein the crystallization accelerator-containing coating film contains barium carbonate and a thickener, and a Ba concentration in the crystallization accelerator-containing coating film is 1.0×10¹⁵ to 1.0×10¹⁸ atoms/cm².

7. The quartz glass crucible according to claim 1,
wherein a B concentration in a second depth region within two-thirds of a wall thickness of the crucible base body from the outer surface of the crucible base body is 0.02 to 0.05 ppm.

8. The quartz glass crucible according to claim 1,
wherein an Mg concentration in a second depth region within two-thirds of a wall thickness of the crucible base body from the outer surface of the crucible base body is 0.02 to 0.4 ppm.

9. The quartz glass crucible according to claim 1,
wherein a Cr concentration in a second depth region within two-thirds of a wall thickness of the crucible base body from the outer surface of the crucible base body is 0.02 to 0.08 ppm.

10. The quartz glass crucible according to claim 7,
wherein the B concentration in the second depth region within two-thirds of the wall thickness of the crucible base body from the outer surface of the crucible base body is higher than a B concentration in a third depth region within 2 mm from an inner surface of the crucible base body.

11. The quartz glass crucible according to claim 8,
wherein the Mg concentration in the second depth region within two-thirds of the wall thickness of the crucible base body from the outer surface of the crucible base body is higher than an Mg concentration in a third depth region within 2 mm from an inner surface of the crucible base body.

12. The quartz glass crucible according to claim 9,
wherein the Cr concentration in the second depth region within two-thirds of the wall thickness of the crucible base body from the outer surface of the crucible base body is higher than a Cr concentration in a third depth region within 2 mm from an inner surface of the crucible base body.

13. A quartz glass crucible comprising:
a crucible base body made of silica glass; and
a crystallization accelerator-containing coating film formed on an outer surface of the crucible base body,
wherein a fictive temperature of the outer surface of the crucible base body is lower than a fictive temperature of an inside of the base body at a depth of 5 mm from the outer surface by 50° C. or more.

14. A method for producing a silicon single crystal, comprising:
pulling up a silicon single crystal by a CZ method using the quartz glass crucible according to claim 1.
